(19) United States
(12) Patent Application Publication
(10) Pub. No.: US 2024/0224471 A1
(43) Pub. Date: Jul. 4, 2024

(54) COOLING CASE AND COLD PLATE STRUCTURE FOR COOLING PRINTED CIRCUIT BOARDS

(71) Applicant: ASELSAN ELEKTRONIK SANAYI VE TICARET ANONIM SIRKETI, Ankara (TR)

(72) Inventors: Murat PARLAK, Ankara (TR); Ahmet Sahin SEN, Ankara (TR); Vedat YAGCI, Ankara (TR)

(73) Assignee: ASELSAN ELEKTRONIK SANAYI VE TICARET ANONIM SIRKETI, Ankara (TR)

(21) Appl. No.: 18/525,915

(22) Filed: Dec. 1, 2023

(30) Foreign Application Priority Data
Dec. 28, 2022 (TR) 2022/020902

(51) Int. Cl. H05K 7/20; H05K 1/14; H05K 7/14

(52) U.S. Cl. CPC H05K 7/20545; H05K 1/141; H05K 7/1404

(57) ABSTRACT

A printed circuit board cooling structure is provided, where a printed circuit board (PCB) is fixed to the printed circuit board cooling structure for cooling and meeting mechanical and electrical requirements. The printed circuit board cooling structure includes a cooling case in which printed circuit boards (PCB) are cooled with air or fluid, and a cold plate structure which is placed in the case made from a slit opened in the relevant board area of the cooling case, transfers the heat to chassis (case) wall, and eliminates wedge mechanism.

### CROSS REFERENCE TO THE RELATED APPLICATIONS

This application is based upon and claims priority to Turkish Patent Application No. 2022/020902, filed on Dec. 28, 2022, the entire contents of which are incorporated herein by reference.

### TECHNICAL FIELD

The invention relates to a cooling case in which printed circuit boards (PCB) are cooled with air or fluid, and to a cold plate structure which is placed in the case made from a slit opened in the relevant board area of the cooling case, transfers the heat to chassis (case) wall, and eliminates wedge mechanism.

### BACKGROUND

Printed circuit boards (PCB) must be fixed to a mechanic for both cooling purposes and to meet mechanical and electrical requirements in military electronic packaging. Mechanically, it must be resistant to shock and vibration, and electrically, necessary connectors must be combined with each other. Especially cooling of boards with very high heat loads by heat conduction method provides great advantages on many platforms. There can be more than one board in a case, but if one or more of these boards have excessive heat load compared to other boards, entire cooling architecture can be changed.

In the state of the art, the electronic board (PCB) is used together with a wedge mechanism. This structure, which is connected to each other on the outside, is mounted to the case by sliding it from upper region. Due to the gap and interface resistances inside the wedge lock mechanisms used, it creates higher thermal resistance. The biggest problem in the state of the art is that the thermal resistance is 0.2° C./W in the hollow mechanical part and 0.5° C./W on the wedge-lock surface. In this case, the heat cannot equally distributed, and the combined resistance of the heat radiated in parallel varies between 0.143-0.2° C./W. In this situation, when a heat load of 70W is transferred from only one wall through the wedge mechanism, temperature increase of 10° C. can occur through this passage.

U.S. Pat. No. 4,962,444A relates to a cooling system comprising a chassis with cold ribs for cooling an electronic board in an electronic system. Without changing the cold plate mounting approach in the prior art, a new and effective fluid path is designed to allow the cooling fluid to reach the edge of the cold plate. However, there is no configuration that eliminates the thermal interface resistances between the cold plate and the case, provides mounting without a board holder, and eliminates the thermal resistances from the board holder.

As a result, due to the abovementioned disadvantages and the inadequacy of the existing solutions on the subject, a development in the relevant technical field has become necessary.

### SUMMARY

The invention is inspired by the present invention and aims to solve the abovementioned problems.

Main object of the invention is to provide a cooling case and cold plate in which the cold plate is mounted to the cooling case by sliding from the side wall without extending the fluid or air path, thus providing a low temperature increase at high heat loads.

Another of the invention is to provide contact with the coolant of the cooling case by means of cooling fins located on the edge of the cold plate.

A further object of the invention is to provide a sealed cooling plate flange which fits into the cooling case by means of screws and gaskets.

A further object of the invention is to provide an embodiment in which the wedge mechanism is not used, and hence there is no higher thermal resistance due to the gap and interface resistances inside the wedge lock mechanisms used.

To fulfil the abovementioned objects, the invention is a printed circuit board cooling structure, in which the printed circuit board is fixed for both cooling and meeting mechanical and electrical requirements, comprising:
a cold plate and
a cooling case which provides cooling by air or fluid, and where the cold plate is positioned,
characterized by comprising:
at least one plate slot which is opened on a side of the cooling case, through which the cold plate can be inserted into the cooling case, and
fins which are configured on a side of the cold plate corresponding to the plate slot, allowing high heat load to be removed from the cold plate.

The structural and characteristic features and all advantages of the invention will be more clearly understood by means of the figures given below and the detailed description written by making references to these figures, and therefore, the evaluation should be made by taking these figures and detailed description into consideration.

### BRIEF DESCRIPTION OF THE DRAWINGS

FIG. 1 is a view of the prior art with wedge mechanism.

FIG. 2 is a view of the cold plate mounted in an air cooled or fluid cooled cold case.

FIG. 3 is the top assembly and detail view of the prior art cold plate with wedge mechanism.

FIG. 4 is the top assembly and detail view of the inventive sliding cold plate.

FIG. 5 is a view of the assembly of the inventive sliding cold plate to the air cooled case.

FIG. 6 is an exploded view of the inventive sliding cold plate.

FIG. 7 is a top thermal model view of the inventive sliding cooling case.

FIG. 8 is a view of the thermal model of the prior art cold plate and cooling case with wedge mechanism.

### DESCRIPTION OF PART REFERENCES

1. Printed circuit board
2. Wedge lock mechanism
10. Cooling case
11. Plate slot
20. Cold plate
21. Fins
22. Outer cover
23. Outer cover gasket
24. Case gasket
25. Screw
26. Thermal interface material

### DETAILED DESCRIPTION OF THE EMBODIMENTS

In this detailed description, preferred embodiments of the inventive cooling case and cold plate are described only for a better understanding of the subject matter.

In the invention, an embodiment is provided which improves heat conduction cooling in a way to meet other requirements according to a previously known method. In this embodiment, a method has been developed to minimize the thermal performance loss due to the wedge mechanism of a board having a very high heat load. With this method, a slot is opened in the relevant board area of the case and a plate called cold plate, which is used to bring the heat from the electronic elements to the chassis (case) wall, is inserted into the case from the outside. In the embodiment of the subject matter of the invention, the wedge mechanism is completely removed. The edges of the sliding plate are kept wide, fins are added to increase the cooling efficiency and gaskets are added to the flange on it to ensure sealing, and it is aimed to obtain a highly efficient, easy to manufacture and thermally very advantageous structure for both fluid cooled cases and air cooled cases.

The cooling case (10) and cold plate (20) configuration for cooling the printed circuit boards (1) of the invention comprises, in its most basic form, a fluid or air cooled cooling case (10) and a cold plate (20) placed in the cooling case (10).

The most important distinguishing feature the embodiment of the subject matter of the invention from the prior art is an opening of a plate slot (11) on the side of the cooling case (10). The plate slot (11) enables the cold plate (20) to be inserted into the cooling case (10) from the side. In addition, the heat is removed directly from the wall of the cooling chassis by means of fins (21) configured on the side of the cold plate corresponding to the plate slot, which provide high heat load removal from the cold plate.

In the embodiment of the subject matter of the invention, there is at least one outer cover (22) which closes the plate slot (11), and the plate slot (11) is configured on the cooling case (10) to allow the cold plate (20) to enter the cooling case (10). There is also an outer cover gasket (23) configured between the fins (21) and the outer cover to ensure sealing. The inventive embodiment further comprises a case gasket (24) configured between the fins (21) and the cooling case (10) for sealing. Herein, the outer cover (22) is fixed to the cooling case (10) and the sealing is completed by screws and the outer cover gasket (23). In addition, a thermal interface material (26) is provided on the side wall of the cold plate (20). The thermal interface material (26) reduces the thermal resistance on the side wall of the cold plate (20).

In the embodiment of the subject matter of the invention, the PCB or elements to be cooled and the cold plate (20) are connected to each other with screws and move together. By changing the material of the cold plate (20), the conduction resistance of the heat until the edge of the board can be managed. However, the wedge mechanism is the biggest problem in the heat transfer from the cold plate to the case. Although the wedge structure is practical and provides convenience in disassembly and assembly, it makes a very serious problem in cooling. In practice, boards are not dismantled unless there is a problem, but as long as the wedge mechanism is there, the board always has to work hot. This problem has been identified and the structure of the invention allows the board to be installed together with the cold plate or separately. While the heat conduction continues to the coolant without any interruption on one edge, on the other edge, it encounters very low thermal resistance compared to the conventional wedge structure by pressing the case edge with a large surface. As a result, the products will be cooler, the performance will be higher, and the lifetime will be longer.

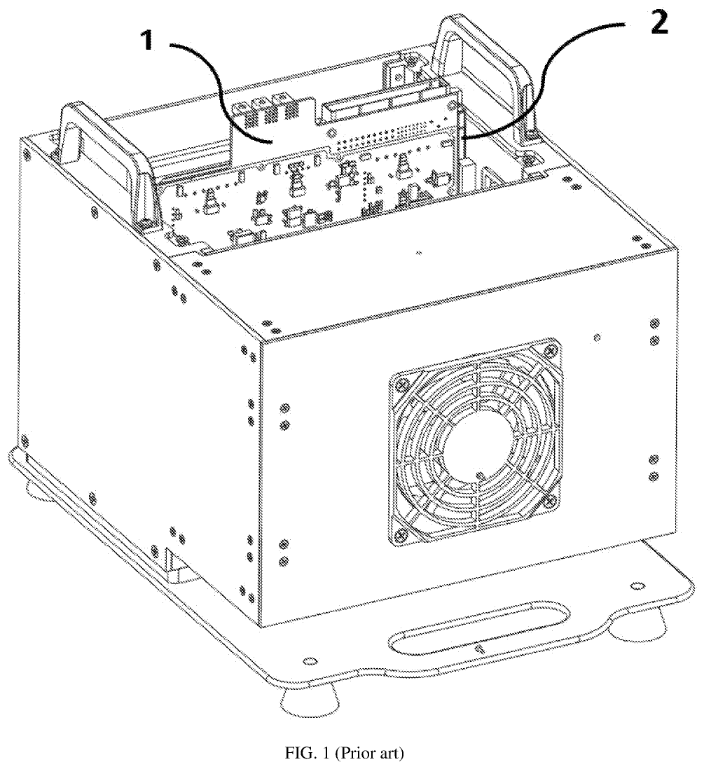

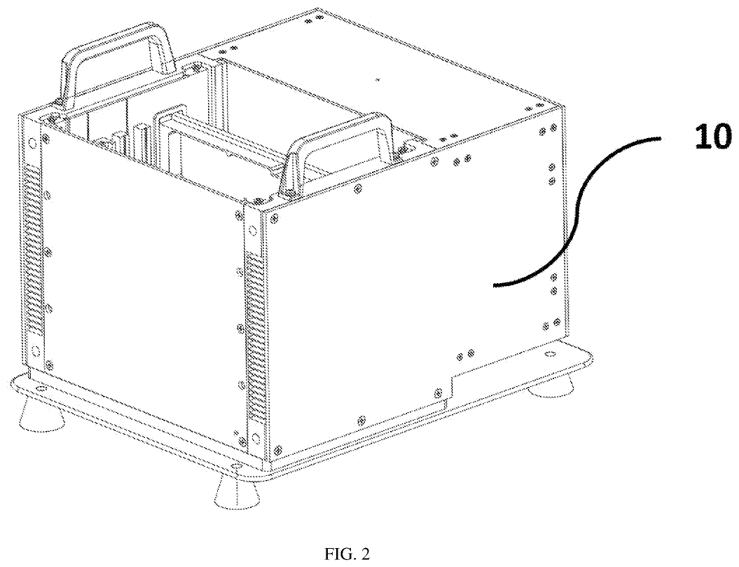

FIG. 1 shows the assembly of the printed circuit board (1) into the cooling case with the wedge lock mechanism (2). Herein, the wedge mechanism is used to connect the board to the case rather than providing heat transfer. The own cold plate on the board is designed flat so that it can conduct heat to the sliding cold plate (20). Afterwards, the board can be disassembled and assembled with the help of the wedge mechanism for easy disassembly and assembly.

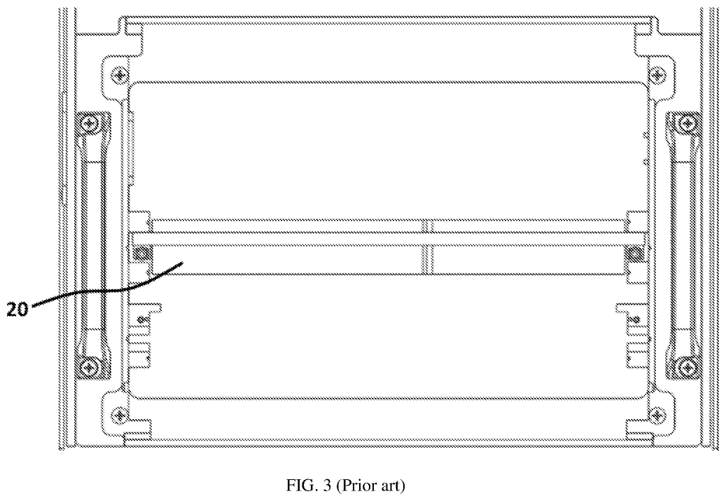

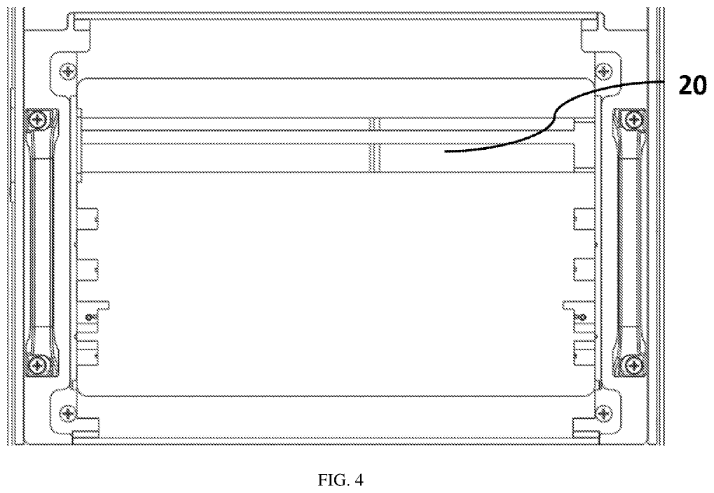

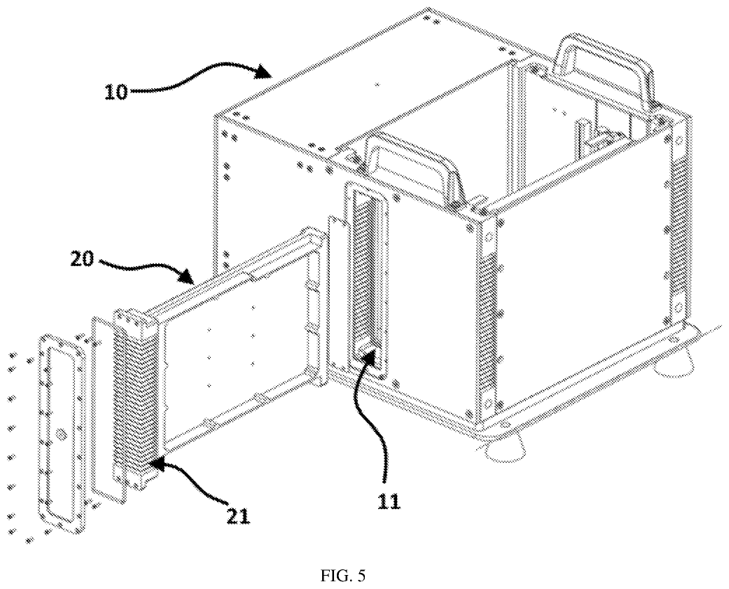

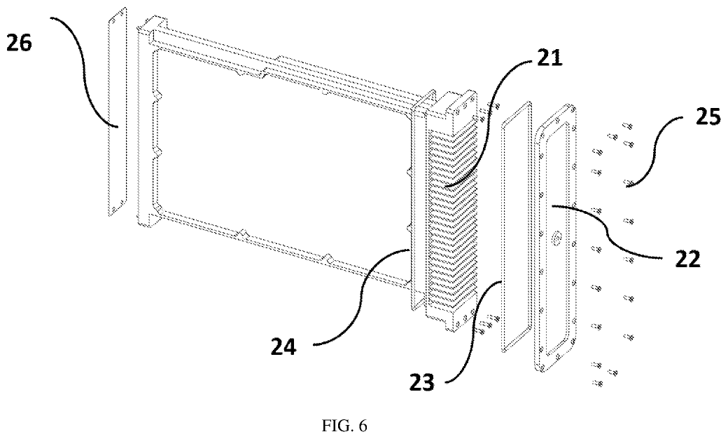

FIGS. 3 and 4 show two different mechanisms, namely, a cold plate (2) with a wedge lock mechanism (2) in the cooling case (10) and the inventive sliding cold plate (20) from top. The 8-10° C. improvement in cooling can allow the volume of the cooling unit (exchanger) to be used in a fluid cooled system to be reduced by up to half.

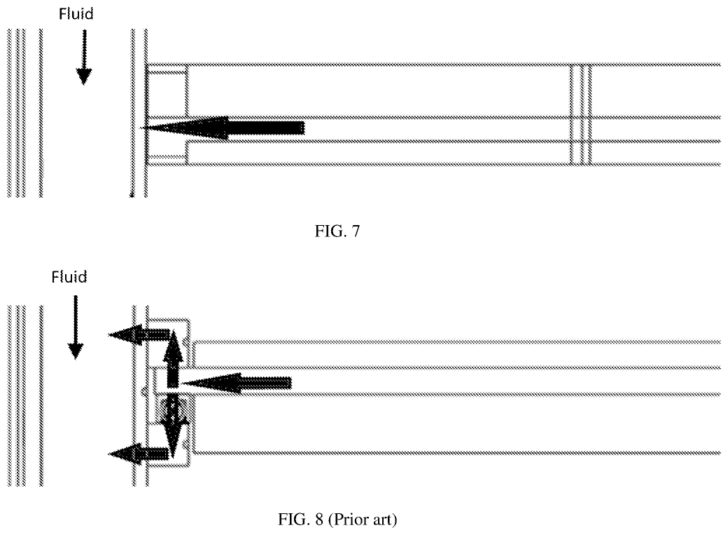

FIG. 7 and FIG. 8 show the difference in heat conduction paths between two different cooling methods. In the wedge mechanism structure, the heat is divided into two separate lines, while there is a loss due to resistances at the metal-metal interface and the wedge mechanism. In the embodiment of the subject matter of the invention, the heat reaches the cooling fins (21) of the cold plate (20). In addition, by pressing on the wall of the cooling case (10) from a large surface, it also transfers some of the heat to the case wall. By means of the gasketed structure on one side of the plate, it is sufficient to take sealing measures on one side.

Since the cold plate (20) is on the cooling fins (21), it will directly contact with the cooler and the performance loss of 10-11° C. that may occur in a board with a total heat load of 100-120W, which would occur with the other method, will be eliminated. In addition, it is very practical to disassemble and assemble the board. In addition, with the sealing measures taken, the same structure can be easily used in both air cooled and fluid cooled structures.

What is claimed is:

1. A printed circuit board cooling structure, with a printed circuit board being fixed to the printed circuit board cooling structure for cooling and meeting mechanical and electrical requirements, comprising:
a cold plate;
a cooling case, wherein the cooling case provides cooling by air or fluid, and the cold plate is positioned in the cooling case;
at least one plate slot, wherein the at least one plate slot is opened on a side of the cooling case, and the cold plate is allowed to be inserted into the cooling case through the at least one plate slot; and
fins, wherein the fins are configured on a side of the cold plate corresponding to the at least one plate slot, allowing a high heat load to be removed from the cold plate.

2. The printed circuit board cooling structure according to claim 1, further comprising at least one outer cover, wherein the at least one outer cover covers the plate slot, and the plate slot is configured on the cooling case to allow the cold plate to enter the cooling case.

3. The printed circuit board cooling structure according to claim 1, further comprising an outer cover gasket, wherein the outer cover gasket is configured between the fins and the at least one outer cover for sealing.

4. The printed circuit board cooling structure according to claim 1, further comprising a case gasket, wherein the case gasket is configured between the fins and the cooling case for sealing.

5. The printed circuit board cooling structure according to claim 2, further comprising at least one screw, wherein the at least one screw is configured for fixing the at least one outer cover to the cooling case and for completing sealing.

6. The printed circuit board cooling structure according to claim 1, further comprising a thermal interface material, wherein the thermal interface material is located on a side wall of the cold plate for reducing thermal resistance.

7. The printed circuit board cooling structure according to claim 2, further comprising an outer cover gasket, wherein the outer cover gasket is configured between the fins and the at least one outer cover for sealing.
